(19) United States
(12) Patent Application Publication
(10) Pub. No.: US 2025/0087507 A1
(43) Pub. Date: Mar. 13, 2025

(54) APPARATUS FOR MANUFACTURING DISPLAY DEVICE, METHOD OF MANUFACTURING DISPLAY DEVICE USING APPARATUS FOR MANUFACTURING DISPLAY DEVICE, AND DISPLAY DEVICE MANUFACTURED BY METHOD OF MANUFACTURING DISPLAY DEVICE

(71) Applicant: Samsung Display Co., LTD., Yongin-si (KR)

(72) Inventor: Hyun Deok IM, Yongin-si (KR)

(73) Assignee: Samsung Display Co., LTD., Yongin-si (KR)

(21) Appl. No.: 18/669,814

(22) Filed: May 21, 2024

(30) Foreign Application Priority Data
Sep. 11, 2023 (KR) 10-2023-0120596

(51) Int. Cl. H01L 21/67; H01L 25/16

(52) U.S. Cl. CPC H01L 21/6715; H01L 21/67259; H01L 25/167

(57) ABSTRACT

An apparatus of manufacturing a display device may include a reservoir that receives ink including a light emitting element and a solvent; an element-movement control module including a pipe part defining an ink channel fluidly connected to the reservoir, and an electrode part disposed on a surface of the pipe part; and a nozzle part that ejects the ink outward. The element-movement control module may operate in a first mode or a second mode. In case that the element-movement control module operates in the first mode, movement of the light emitting element may be unrestricted. In case that the element-movement control module operates in the second mode, the electrode part may form an electric field, and the movement of the light emitting element in the ink channel may be restricted at least in an area corresponding to a position at which the electrode part is disposed.

### CROSS-REFERENCE TO RELATED APPLICATION(S)

This application claims priority to and benefits of Korean patent application No. 10-2023-0120596 under 35 U.S.C. § 119, filed on Sep. 11, 2023, in the Korean Intellectual Property Office, the entire contents of which are incorporated herein by reference.

### BACKGROUND

### 1. Technical Field

Various embodiments relate to an apparatus for manufacturing a display device, a method of manufacturing the display device using the manufacturing apparatus, and a display device manufactured by the method.

### 2. Description of the Related Art

Recently, as interest in information display increases, research and development on display devices have been continuously conducted.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Various embodiments are directed to an apparatus for manufacturing a display device, a method of manufacturing the display device using the manufacturing apparatus, and a display device manufactured by the method, which may adjust the amount of light emitting elements, thus reducing the production cost, and making the amount of light emitting elements provided to a pixel uniform.

An embodiment may provide an apparatus of manufacturing a display device, that may include a reservoir that receives ink including a light emitting element and a solvent; an element-movement control module, the element-movement control module including a pipe part defining an ink channel fluidly connected to the reservoir, and an electrode part disposed on a surface of the pipe part; and a nozzle part that ejects the ink outward. The element-movement control module may operate in a first mode or a second mode. In case that the element-movement control module operates in the first mode, movement of the light emitting element may be unrestricted. In case that the element-movement control module operates in the second mode, the electrode part may form an electric field, and the movement of the light emitting element in the ink channel may be restricted at least in an area corresponding to a position at which the electrode part is disposed.

In an embodiment, the pipe part may include a material that substantially has non-conductivity that allows the electric field formed by the electrode part to be formed in the ink channel.

In an embodiment, the electrode part may include a first side electrode and a second side electrode that form a pair and are spaced apart from each other with the ink channel disposed between the first side electrode and the second side electrode.

In an embodiment, the pipe part may be divided into a plurality of unit areas. The electrode part may be disposed in a unit area among the plurality of unit areas. A volume of the ink channel in the unit area among the plurality of unit areas may correspond to a drop volume of the ink in case that the ink is ejected once from the nozzle part.

In an embodiment, the electrode part may include a plurality of electrode parts spaced apart from each other in a longitudinal direction of the pipe part. The plurality of electrode parts may include a first edge electrode part adjacent to a first end of the unit area among the plurality of unit areas, a second edge electrode part adjacent to a second end of the unit area among the plurality of unit areas, and an inner electrode part disposed between the first edge electrode part and the second edge electrode part.

In an embodiment, the unit area among the plurality of unit areas may include a plurality of sub-unit areas. The plurality of electrode parts may be adjacent to each other with the plurality of sub-unit areas disposed between the plurality of electrode parts.

In an embodiment, a number of the plurality of sub-unit areas may be an even number of 4 or more.

In an embodiment, the element-movement control module may operate for an identical unit time in each of the first mode and the second mode. The unit time may be a time taken for the ink to move through the plurality of sub-unit areas while moving in the ink channel.

In an embodiment, the element-movement control module may operate alternately in the first mode and the second mode.

In an embodiment, the apparatus may further include an inspection part that is spaced apart from the electrode part in the longitudinal direction of the pipe part and may acquire information about the movement of the light emitting element in the ink channel.

In an embodiment, in case that the inspection part acquires movement information that the light emitting element is not normally included in some areas of the ink in the ink channel, after a time based on a distance between the inspection part and the electrode part has elapsed, the element-movement control module may continue to operate in the first mode, and after the unit time has further elapsed, the element-movement control module may enter the second mode.

In an embodiment, the nozzle part and the element-movement control module may be disposed in a print head part. The apparatus may further include a main channel fluidly connecting the print head part with the reservoir; and a body channel formed in the print head part and fluidly connecting the main channel with the ink channel. The body channel may have a diameter greater than a diameter of the ink channel. The element-movement control module may not be disposed in the body channel.

In an embodiment, the print head part may further include a body pipe forming a recycle channel fluidly connected to the ink channel. The recycle channel may be fluidly connected to the reservoir. The body pipe may form space in which the element-movement control module is disposed.

An embodiment may provide a method of manufacturing a display device using an apparatus for manufacturing the display device. The apparatus may include a reservoir that receives ink including a light emitting element and a solvent; an element-movement control module comprising a pipe part defining an ink channel fluidly connected to the reservoir, and an electrode part disposed on a surface of the pipe part, the element-movement control module operating in a first mode or a second mode; and a nozzle part that ejects the ink outward. The method may include patterning a first electrode and a second electrode on a base layer; supplying the ink provided from the nozzle part onto the base layer; and aligning the light emitting element, based on an electric field formed between the first electrode and the second electrode. The supplying of the ink may include operating the element-movement control module in the first mode; and operating the element-movement control module in the second mode. The operating of the element-movement control module in the first mode may include passing the light emitting element through an area corresponding to a position, at which the electrode part is disposed, in the ink channel. The operating of the element-movement control module in the second mode may include restricting movement of the light emitting element in the area in the ink channel.

In an embodiment, the method may further include patterning a bank defining an opening on the base layer. The supplying of the ink may include providing the ink into the opening of the bank. The aligning of the light emitting element may include supplying a first alignment signal to the first electrode; and supplying a second alignment signal different from the first alignment signal to the second electrode.

In an embodiment, the pipe part may be divided into a plurality of unit areas. The electrode part may be disposed in a unit area among the plurality of unit areas. A volume of the ink channel in the unit area among the plurality of unit areas may correspond to a drop volume of the ink in case that the ink is ejected once from the nozzle part. The electrode part may include a plurality of electrode parts spaced apart from each other in a longitudinal direction of the pipe part.

In an embodiment, the unit area among the plurality of unit areas may include a plurality of sub-unit areas. The plurality of electrode parts may be adjacent to each other with the sub-unit area disposed between the plurality of electrode parts. A number of the plurality of sub-unit areas may be an even number of 4 or more.

In an embodiment, the operating of the element-movement control module in the first mode and the operating of the element-movement control module in the second mode may alternate.

In an embodiment, the supplying of the ink may include supplying the ink of a first drop volume to a first area on the base layer; and the supplying of the ink of a second drop volume to a second area on the base layer. At least the light emitting element may be included in the ink of each of the first drop volume and the second drop volume.

An embodiment may provide a display device manufactured by the manufacturing method. The display device may include a light emitting element aligned between the first electrode and the second electrode; a first connection electrode electrically connected to a first end of the light emitting element; and a second connection electrode electrically connected to a second end of the light emitting element.

### BRIEF DESCRIPTION OF THE DRAWINGS

The above and other aspects and features of the disclosure will become more apparent by describing in detail embodiments thereof with reference to the attached drawings, in which:

FIG. 1 is a schematic perspective view illustrating a light emitting element in accordance with an embodiment.

FIG. 2 is a schematic sectional view illustrating a light emitting element in accordance with an embodiment.

FIG. 3 is a schematic plan view illustrating a display device in accordance with an embodiment.

FIG. 4 is a schematic sectional view illustrating a display device in accordance with an embodiment.

FIG. 5 is a schematic perspective view illustrating an apparatus for manufacturing the display device in accordance with an embodiment.

FIG. 6 is a block diagram illustrating the manufacturing apparatus in accordance with an embodiment.

FIG. 7 is a schematic sectional view illustrating a print head unit (or part) in accordance with an embodiment.

FIG. 8 is a schematic sectional view illustrating an element-movement control module in accordance with an embodiment.

FIGS. 9 and 10 are schematic sectional views illustrating the element-movement control module according to an embodiment for describing an arrangement structure of an electrode part in accordance with an embodiment.

FIG. 11 is a schematic view illustrating an operation mode of an element-movement control module in accordance with an embodiment.

FIG. 12 is a schematic sectional view for describing an operation mode of the element-movement control module in accordance with an embodiment.

FIG. 13 is a schematic sectional view illustrating a structure in which the element-movement control module in accordance with an embodiment further includes an inspection part.

FIG. 14 is a flowchart illustrating a method of manufacturing the display device using the manufacturing apparatus in accordance with an embodiment.

FIG. 15 is a flowchart illustrating in detail steps in the method of manufacturing the display device using the manufacturing apparatus in accordance with an embodiment.

FIGS. 16, 21, and 22 are schematic sectional views illustrating, by process steps, the method of manufacturing the display device in accordance with an embodiment.

FIGS. 17 and 18 are schematic views illustrating operation aspects of the element-movement control module in accordance with an embodiment.

FIGS. 19 and 20 are schematic views illustrating ejection of ink in accordance with an embodiment.

### DETAILED DESCRIPTION OF THE EMBODIMENTS

As the disclosure allows for various changes and numerous embodiments, embodiments will be illustrated in the drawings and described in detail in the written description. However, this is not intended to limit the disclosure to particular modes of practice, and it is to be appreciated that all changes, equivalents, and substitutes that do not depart from the spirit and technical scope of the disclosure are encompassed in the disclosure.

In the drawings, sizes, thicknesses, ratios, and dimensions of the elements may be exaggerated for ease of description and for clarity. Like numbers refer to like elements throughout.

It will be understood that, although the terms “first”, “second”, etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will be further understood that the terms “comprise”, “include”, “have”, etc. when used in the disclosure, specify the presence of stated features, integers, steps, operations, elements, components, and/or combinations of them but do not preclude the presence or addition of one or more other features, integers, steps, operations, elements, components, and/or combinations thereof.

Furthermore, in case that a first part such as a layer, a film, a region, or a plate is disposed on a second part, the first part may be not only directly on the second part but a third part may intervene between them. In addition, when it is expressed that a first part such as a layer, a film, a region, or a plate is formed on a second part, the surface of the second part on which the first part is formed is not limited to an upper surface of the second part but may include other surfaces such as a side surface or a lower surface of the second part. To the contrary, in case that a first part such as a layer, a film, a region, or a plate is under a second part, the first part may be not only directly under the second part but a third part may intervene between them.

It will be understood that when an element (or a region, a layer, a portion, or the like) is referred to as “being on”, “connected to” or “coupled to” another element in the specification, it can be directly disposed on, connected or coupled to another element mentioned above, or intervening elements may be disposed therebetween.

It will be understood that the terms “connected to” or “coupled to” may include a physical or electrical connection or coupling.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Embodiments may be described and illustrated in the accompanying drawings in terms of functional blocks, units, and/or modules.

Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies.

In the case of the blocks, units, and/or modules being implemented by microprocessors or other similar hardware, they may be programmed and controlled using software (for example, microcode) to perform various functions discussed herein and may optionally be driven by firmware and/or software.

It is also contemplated that each block, unit, and/or module may be implemented by dedicated hardware, or as a combination of dedicated hardware to perform some functions and a processor (for example, one or more programmed microprocessors and associated circuitry) to perform other functions.

Each block, unit, and/or module of embodiments may be physically separated into two or more interacting and discrete blocks, units, and/or modules without departing from the scope of the disclosure.

Further, the blocks, units, and/or modules of embodiments may be physically combined into more complex blocks, units, and/or modules without departing from the scope of the disclosure.

Various embodiments relate to an apparatus for manufacturing a display device, a method of manufacturing the display device using the manufacturing apparatus, and a display device manufactured by the method. Hereinafter, an apparatus for manufacturing a display device, a method of manufacturing the display device using the manufacturing apparatus, and the display device manufactured by the method in accordance with embodiments will be described with reference to the accompanying drawings.

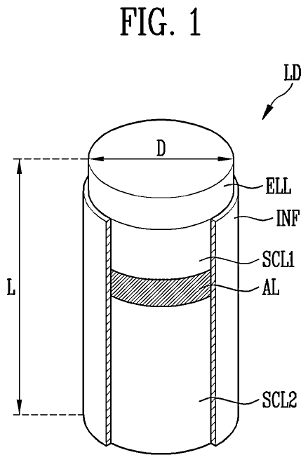

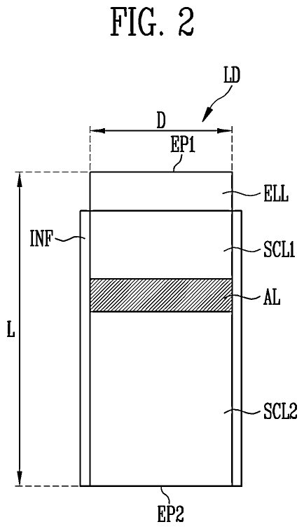

First, a light emitting element LD in accordance with an embodiment will be described with reference to FIGS. 1 and 2. FIG. 1 is a schematic perspective view illustrating a light emitting element in accordance with an embodiment. FIG. 2 is a schematic sectional view illustrating a light emitting element in accordance with an embodiment.

The light emitting element LD may be configured to emit light. The light emitting element LD may include a first semiconductor layer SCL1, a second semiconductor layer SCL2, and an active layer AL disposed between the first semiconductor layer SCL1 and the second semiconductor layer SCL2. In an embodiment, the first semiconductor layer SCL1, the active layer AL, and the second semiconductor layer SCL2 may be successively stacked in a longitudinal direction (L) of the light emitting element LD. In an embodiment, the light emitting element LD may further include an electrode layer ELL and an insulating film INF.

The light emitting element LD may have various shapes. For example, the light emitting element LD may have a pillar-like shape extending in a direction. Here, the term “pillar-like shape” may include a rod-like shape and a bar-like shape such as a cylindrical shape and a prismatic shape that is longer in a longitudinal direction L (for example, to have an aspect ratio greater than 1), and the cross-sectional shape thereof is not limited to a particular shape.

The light emitting element LD may include a first end EP1 and a second end EP2. In an embodiment, the first semiconductor layer SCL1 may be adjacent to the first end EP1 of the light emitting element LD. The second semiconductor layer SCL2 may be adjacent to the second end EP2. In an embodiment, the electrode layer ELL may be adjacent to the first end EP1.

The light emitting element LD may be manufactured by etching semiconductor layers that are successively stacked. The light emitting element LD may have a size ranging from the nanometer scale to the micrometer scale. For example, a diameter D (or a width) of the light emitting element LD and the length L of the light emitting element LD may each range from the nanoscale to the microscale. However, the disclosure is not limited to the foregoing example.

The first semiconductor layer SCL1 may include a first conductive semiconductor. The first semiconductor layer SCL1 may be disposed on the active layer AL and include a semiconductor layer having a type different from that of the second semiconductor layer SCL2. For example, the first semiconductor layer SCL1 may include a P-type semiconductor layer. For example, the first semiconductor layer SCL1 may include one or more semiconductor materials selected from the group consisting of InAlGaN, GaN, AlGaN, InGaN, AlN, and InN, and may include a P-type semiconductor layer doped with a first conductive dopant such as Ga, B, and Mg. However, the disclosure is not limited to the foregoing example. The first semiconductor layer SCL1 may include various materials.

The active layer AL may be disposed between the first semiconductor layer SCL1 and the second semiconductor layer SCL2. The active layer AL may include a single-quantum well structure or a multi-quantum well structure. The position of the active layer AL may be changed in various ways depending on the type of the light emitting element LD, rather than being limited to a specific example.

The second semiconductor layer SCL2 may include a second conductive semiconductor. The second semiconductor layer SCL2 may be disposed on the active layer AL and include a semiconductor layer of a type different from that of the first semiconductor layer SCL1. For example, the second semiconductor layer SCL2 may include an N-type semiconductor layer. For example, the second semiconductor layer SCL2 may include one or more selected from the group consisting of InAlGaN, GaN, AlGaN, InGaN, AlN, and InN, and may include an N-type semiconductor layer doped with a second conductive dopant such as Si, Ge, and Sn. However, the disclosure is not limited to the foregoing example. The second semiconductor layer SCL2 may include various materials.

In the case where a voltage of a threshold voltage or more is applied between the first end EP1 and the second end EP2 of the light emitting element LD, an electron-hole pair in the active layer AL may be recombined, and the light emitting element LD may emit light. Since light emission of the light emitting element LD can be controlled based on the foregoing principle, the light emitting element LD may be used as a light source in various devices.

The insulating film INF may be disposed on a surface of the light emitting element LD. The insulating film INF may enclose an outer surface of the active layer AL, and may also enclose a portion of each of the first semiconductor layer SCL1 and the second semiconductor layer SCL2. The insulating film INF may have a single-layer or multilayer structure.

The insulating film INF may allow the first end EP1 and the second end EP2 of the light emitting element LD that have different polarities to be exposed. For example, the insulating film INF allows respective ends of the electrode layer ELL and the second semiconductor layer SCL2 that are adjacent to the first end EP1 and the second end EP2 of the light emitting element LD to be exposed. The insulating film INF may secure electrical stability of the light emitting element LD. Furthermore, the insulating film INF may minimize surface defects of the light emitting element LD, thus enhancing the lifespan and efficiency of the light emitting element LD. In the case where a plurality of light emitting elements LD are disposed adjacent to each other, the insulating film INF may prevent a short-circuit defect between the light emitting elements LD from occurring.

For example, the insulating film INF may include one or more materials selected from the group consisting of silicon oxide (SiOₓ), silicon nitride (SiNₓ), silicon oxynitride (SiOₓN_{y}), aluminum oxide (AlₓO_{y}), and titanium oxide (TiOₓ). However, the disclosure is not limited to the foregoing example.

The electrode layer ELL may be disposed on the first semiconductor layer SCL1. The electrode layer ELL may be adjacent to the first end EP1. The electrode layer ELL may be electrically connected to the first semiconductor layer SCL1. A portion of the electrode layer ELL may be exposed. For example, the insulating film INF allows a surface of the electrode layer ELL to be exposed. The electrode layer ELL may be exposed in an area corresponding to the first end EP1. In an embodiment, a side surface of the electrode layer ELL may be exposed. For example, the insulating film INF may cover a side surface of each of the first semiconductor layer SCL1, the active layer AL, and the second semiconductor layer SCL2, and may not cover at least a portion of the side surface of the electrode layer ELL. In this case, electrical connection of the electrode layer ELL adjacent to the first end EP1 with respect to other components may be facilitated. In an embodiment, the element insulating film INF may allow not only the side surface of the electrode layer ELL but also a portion of the side surface of the first semiconductor layer SCL1 and/or the second semiconductor layer SCL2 to be exposed.

In an embodiment, the electrode layer ELL may be an ohmic contact electrode. However, the disclosure is not limited to the foregoing example. For example, the electrode layer ELL may be a Schottky contact electrode.

In an embodiment, the electrode layer ELL may be substantially transparent. For example, the electrode layer ELL may include indium tin oxide (ITO). Hence, the electrode layer ELL allows emitted light to pass through. However, the disclosure is not limited to the foregoing example.

The structure, the shape, and the like of the light emitting element LD are not limited to the foregoing examples. In an embodiment, the light emitting element LD may have various structures and shapes. For example, the light emitting element LD may further include an additional electrode layer which is disposed on a surface of the second semiconductor layer SCL2 and is adjacent to the second end EP2.

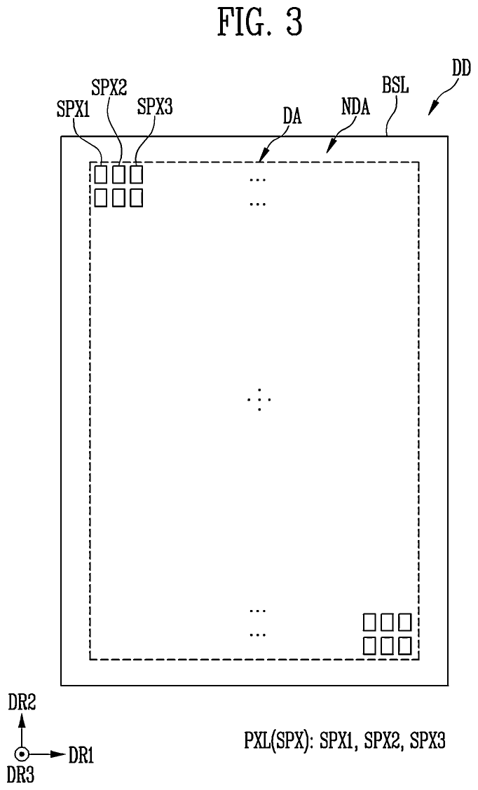

FIG. 3 is a schematic plan view illustrating a display device DD in accordance with an embodiment.

Referring to FIG. 3, the display device DD may include a base layer BSL, and pixels PXL disposed on the base layer BSL. Although not illustrated in the drawing, the display device DD may further include a driving circuit part (for example, a scan driver and a data driver), lines, and pads which are configured to drive the pixels PXL.

The display device DD (or the base layer BSL) may include a display area DA and a non-display area NDA. The non-display area NDA may be an area other than the display area DA. The non-display area NDA may enclose at least a portion of the display area DA.

The base layer BSL may form a base surface of the display device DD. The base layer BSL may be a rigid or flexible substrate or film. For example, the base layer BSL may be a rigid substrate made of glass or reinforced glass, a flexible substrate (or a thin film) formed of plastic or metal, or at least one insulating layer. The material and/or properties of the base layer BSL are not particularly limited. In an embodiment, the base layer BSL may be substantially transparent. Here, the words “substantially transparent” may mean that light can pass through the base layer BSL with a transmittance of a given value or more. In an embodiment, the base layer BSL may be translucent or opaque. Furthermore, the base layer BSL may include reflective material depending on the embodiment.

The display area DA may refer to an area in which the pixels PXL are disposed. The non-display area NDA may refer to an area in which the pixels PXL are not disposed. The driving circuit part, the lines, and the pads which are connected to the pixels PXL of the display area DA may be disposed in the non-display area NDA.

In an embodiment, the pixels PXL (or sub-pixels SPX) may be arranged or disposed according to a stripe (for example, an S-stripe or D-stripe) or PENTILE™ arrangement structure. However, the disclosure is not limited the aforementioned example, and various embodiments may be applied to the disclosure.

In accordance with an embodiment, the pixel PXL (or the sub-pixels SPX) may include a first sub-pixel SPX1, a second sub-pixel SPX2, and a third sub-pixel SPX3. Each of the first sub-pixel SPX1, the second sub-pixel SPX2, and the third sub-pixel SPX3 may be a sub-pixel. At least one first sub-pixel SPX1, at least one second sub-pixel SPX2, and at least one third sub-pixel SPX3 may form a pixel unit which may emit various colors of light.

For example, each of the first sub-pixel SPX1, the second sub-pixel SPX2, and the third sub-pixel SPX3 may emit a single color of light. For instance, the first sub-pixel SPX1 may be a red pixel configured to emit light in red (for example, first color), the second sub-pixel SPX2 may be a green pixel configured to emit light in green (for example, second color), and the third sub-pixel SPX3 may be a blue pixel configured to emit light in blue (for example, third color). In accordance with an embodiment, the number of second sub-pixels SPX2 may be greater than the number of first sub-pixels SPX1, or the number of third sub-pixels SPX3. The colors, types, and/or numbers of first sub-pixels SPX1, second sub-pixels SPX2, and the third sub-pixels SPX3 which form each pixel unit are not limited to a specific example.

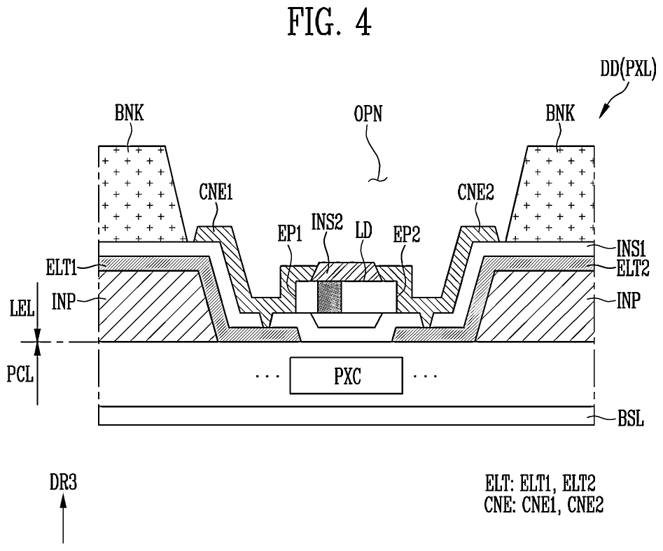

Hereinafter, a sectional structure of the display device DD in accordance with an embodiment will be described with reference to FIG. 4. FIG. 4 is a schematic sectional view illustrating the display device DD in accordance with an embodiment.

Referring to FIG. 4, the display device DD may include a pixel circuit layer PCL, and a light-emitting-element layer LEL.

The pixel circuit layer PCL may be a layer including a pixel circuit PXC configured to drive the light emitting elements LD. The pixel circuit layer PCL may include a base layer BSL, conductive layers formed to form pixel circuits, and insulating layers disposed on the conductive layers.

The light-emitting-element layer LEL may be disposed on the pixel circuit layer PCL. In an embodiment, the light-emitting-element layer LEL may include the light emitting elements LD. The light-emitting-element layer LEL may include an insulating pattern INP, an alignment electrode ELT, a first insulating layer INS1, a bank BNK, a second insulating layer INS2, and a connection electrode CNE.

The insulating pattern INP may be disposed on the pixel circuit layer PCL, and may have a shape extending (or protruding) in a thickness direction of the base layer BSL (for example, a third direction DR3). At least a portion of each of the first electrode ELT1 and the second electrode ELT2 may be disposed on the insulating pattern INP to form a reflective wall.

The alignment electrode ELT may have a conductive structure provided to form an electric field for aligning the light emitting elements LD. The alignment electrode ELT may include a first electrode ELT1 and a second electrode ELT2 that are spaced apart from each other (spaced apart from each other in a direction in which the light emitting elements LD extend).

In an embodiment, the first electrode ELT1 may be a first alignment electrode to which an AC signal can be supplied to align the light emitting elements LD. The first electrode ELT1 may be an electrode to which an anode signal can be supplied to allow the light emitting elements LD to emit light. The second electrode ELT2 may be a second alignment electrode to which a ground signal can be supplied to align the light emitting elements LD. The second electrode ELT2 may be an electrode to which a cathode signal can be supplied to allow the light emitting elements LD to emit light. In an embodiment, the first electrode ELT1 may be electrically connected to a first connection electrode CNE1. The second electrode ELT2 may be electrically connected to a second connection electrode CNE2.

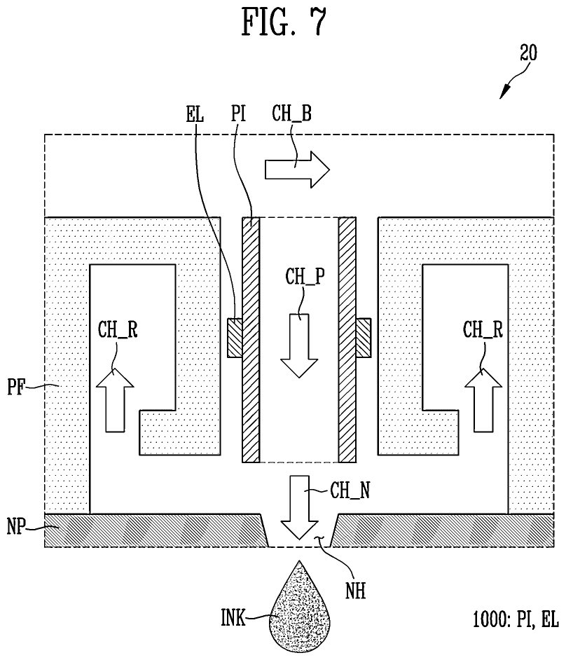

The first electrode ELT1 and the second electrode ELT2 may be respectively supplied (or provided) with a first alignment signal and a second alignment signal during a process of aligning the light emitting elements LD. For example, ink INK (refer to FIG. 7) including the light emitting elements LD may be supplied (or provided) to an opening OPN, the first alignment signal may be supplied to the first electrode ELT1, and the second alignment signal may be supplied to the second electrode ELT2. Here, the first alignment signal and the second alignment signal may have different waveforms, different potentials, and/or different phases. For example, the first alignment signal may be an AC signal, and the second alignment signal may be a ground signal. However, the disclosure is not limited to the foregoing example. An electric field may be formed between (or over) the first electrode ELT1 and the second electrode ELT2, so that the light emitting elements LD may be aligned between the first electrode ELT1 and the second electrode ELT2 based on the electric field. For example, the light emitting elements LD may be moved (or rotated) by force {for example, dielectrophoresis (DEP) force}derived from the electric field and thus be aligned (or disposed) on the first electrode ELT1 and the second electrode ELT2.

The first insulating layer INS1 may be disposed on the alignment electrode ELT. For example, the first insulating layer INS1 may cover the first electrode ELT1 and the second electrode ELT2. In an embodiment, the first insulating layer INS1 may include inorganic material.

The light emitting elements LD may be disposed on the first insulating layer INS1. The light emitting elements LD may be disposed between the first electrode ELT1 and the second electrode ELT2. The light emitting elements LD may emit light based on an anode signal provided from the first connection electrode CNE1 and a cathode signal provided from the second connection electrode CNE2.

The second insulating layer INS2 may be disposed on the light emitting elements LD. The second insulating layer INS2 may be an anchor. After the light emitting elements LD have been aligned, the second insulating layer INS2 may prevent the light emitting elements LD from being removed from the aligned positions. In an embodiment, the second insulating layer INS2 may include inorganic material or organic material.

The bank BNK may be disposed on the first insulating layer INS1 (for example, the insulating pattern INP). The bank BNK may form space (for example, the opening OPN) configured to receive the ink INK therein.

The first connection electrode CNE1 and the second connection electrode CNE2 may be disposed on the first insulating layer INS1. The first connection electrode CNE1 may be electrically connected to the first end EP1 of each of the light emitting elements LD. The second connection electrode CNE2 may be electrically connected to the second end EP2 of each of the light emitting elements LD.

In an embodiment, the first connection electrode CNE1 and the second connection electrode CNE2 may be patterned at a same time point through a same process. However, the disclosure is not limited to the foregoing example. After any one of the first connection electrode CNE1 and the second connection electrode CNE2 is patterned, the other electrode may be patterned.

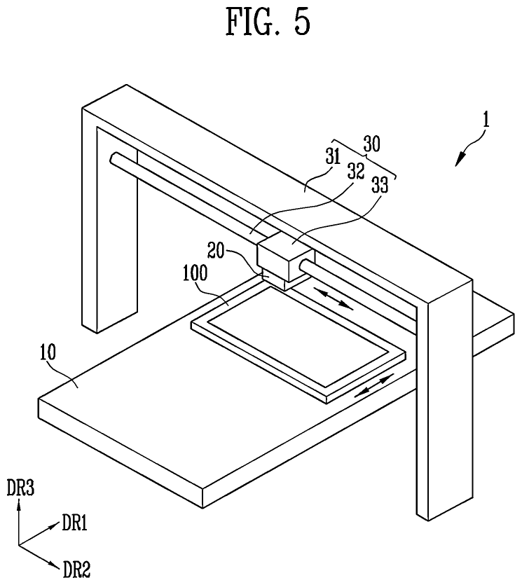

Hereinafter, an apparatus 1 for manufacturing the display device 10 in accordance with an embodiment will be described with reference to FIGS. 5 to 13. Hereinbelow, for the sake of explanation, the apparatus 1 for manufacturing the display device will be referred to simply as the manufacturing apparatus 1.

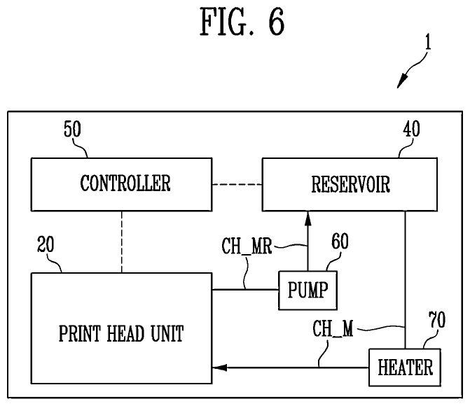

FIG. 5 is a schematic perspective view illustrating the manufacturing apparatus 1 in accordance with an embodiment. FIG. 6 is a block diagram illustrating the manufacturing apparatus 1 in accordance with an embodiment.

Referring to FIGS. 5 and 6, the manufacturing apparatus 1 may include a stage 10, a print head unit (or part) 20, and a movable unit 30. In an embodiment, the manufacturing apparatus 1 may include a reservoir 40, a controller 50, a pump 60, and a heater 70.

In an embodiment, the manufacturing apparatus 1 may include an inkjet printer configured to eject ink INK.

The stage 10 may support a substrate 100. The stage 10 may provide an area on which the substrate 100 is disposed. Here, the substrate 100 may be a base provided to manufacture the display device DD. The substrate 100 may include a pixel circuit layer PCL including a base layer BSL.

In an embodiment, the stage 10 may be formed of rigid material, but is not limited thereto. The stage 10 may have a rectangular shape in a plan view, but is not limited thereto.

In an embodiment, the stage 10 may change the location of the substrate 100. For example, the stage 10 may use a rail or the like to move the substrate 100. In an embodiment, the substrate 100 may be moved in a first direction DR1 by the stage 10.

The print head unit 20 may be disposed above the stage 10. The print head unit 20 may be disposed between the stage 10 and the movable unit 30.

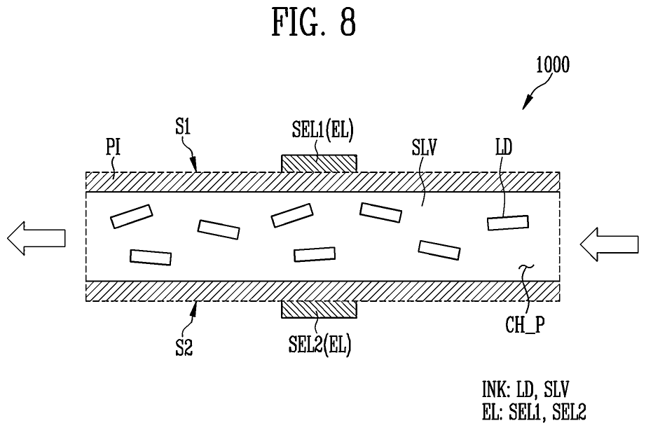

In an embodiment, the print head unit 20 may eject (for example, provide) the ink INK including light emitting elements LD and a solvent SLV (refer to FIG. 8).

In an embodiment, the print head unit 20 may be moved in a second direction DR2 by a guide part 32. As described above, the location of the substrate 100 and the location of the print head unit 20 may be adjusted so that an area on the substrate 100 onto which the ink INK is provided can be adjusted.

The movable unit 30 may be coupled or connected to the print head unit 20. The movable unit 30 may move the print head unit 20.

In an embodiment, the movable unit 30 may include a support part 31, the guide part 32, and a coupling part 33. The support part 31 may support the print head unit 20. The guide part 32 may be coupled or connected to the support part 31 to guide movement of the print head unit 20. The coupling part 33 may be coupled or connected to the print head unit 20 and configured to be movable along the guide part 32.

For example, in the case where there is a need to move the print head unit 20 in the second direction DR2, the coupling part 33 moves along the guide part 32 in the second direction DR2 so that the location of the print head unit 20 can be changed in the second direction DR2.

The reservoir 40 may include space capable of receiving fluid. For example, the fluid (or material) may be contained in the reservoir 40. The ink INK may be provided in the reservoir 40. In an embodiment, the reservoir 40 may be provided separately from the print head unit 20. At least a portion of the reservoir 40 may be disposed in the print head unit 20.

The reservoir 40 may be fluidly connected to the print head unit 20 through a main channel CH_M. The ink INK in the reservoir 40 may be provided to the print head unit 20 through the main channel CH_M. In an embodiment, the temperature on a flow path for the ink INK, including the main channel CH_M, may be changed by a heater 70.

The reservoir 40 may be fluidly connected to the print head unit 20 through a main recycle channel CH_MR. The ink INK in the print head unit 20 may be recycled to the reservoir 40 through the main recycle channel CH_MR.

The controller 50 may control overall operations of the manufacturing apparatus 1. The controller 50 may control the flow of the ink INK in the manufacturing apparatus 1. For example, the controller 50 controls a pump 60 to enable the ink INK to be recycled to the reservoir 40. The controller 50 may control the flow environment of the ink INK through the heater 70. The controller 50 may control the ejection of ink INK from the print head unit 20. The controller 50 may control an element-movement control module 1000 (refer to FIG. 7) such that the movement of the light emitting element LD is limited in the print head unit 20. For example, the controller 50 may change or maintain an operation mode (for example, a first mode M1 and a second mode M2) of the element-movement control module 1000.

In an embodiment, the controller 50 may be implemented as a CPU or a device similar thereto depending on hardware, software, or a combination thereof. In terms of hardware, the controller 50 may be provided in an electronic circuit form that processes electrical signals to perform control functions. In terms of software, the controller 50 may be provided in the form of a program, an application, firmware, or the like that is processed by the hardware-based controller 50.

The print head unit 20 including the element-movement control module 1000 will be described with reference to FIGS. 7 to 10. In an embodiment, the element-movement control module 1000 may be included in the print head unit 20. However, the disclosure is not limited to the aforementioned example. In an embodiment, the element-movement control module 1000 may be disposed in an area provided separately from the print head unit 20. Hereinafter, for the sake of convenience in the explanation, descriptions will be based on an embodiment in which the element-movement control module 1000 is disposed in the print head unit 20.

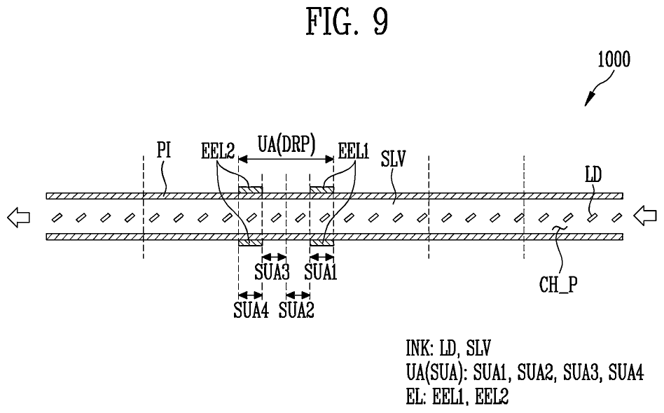

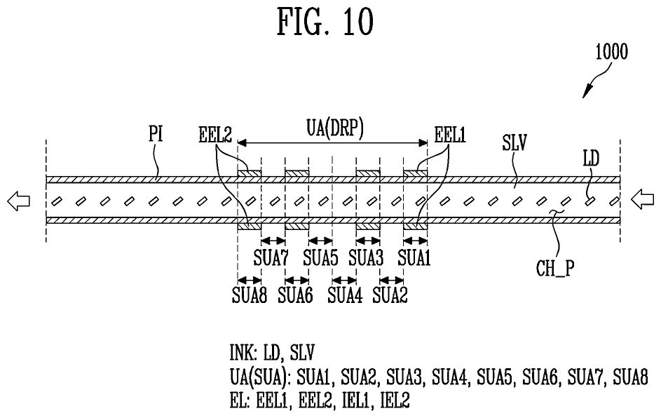

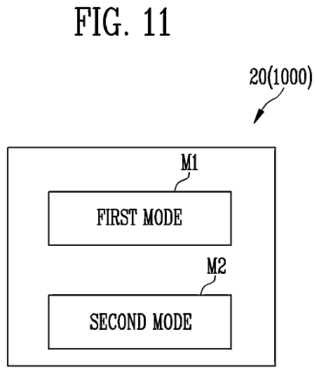

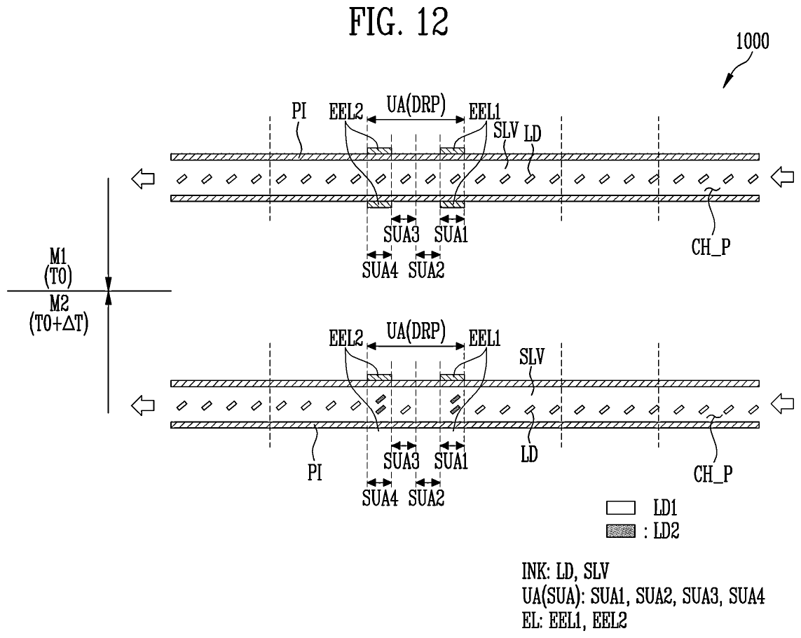

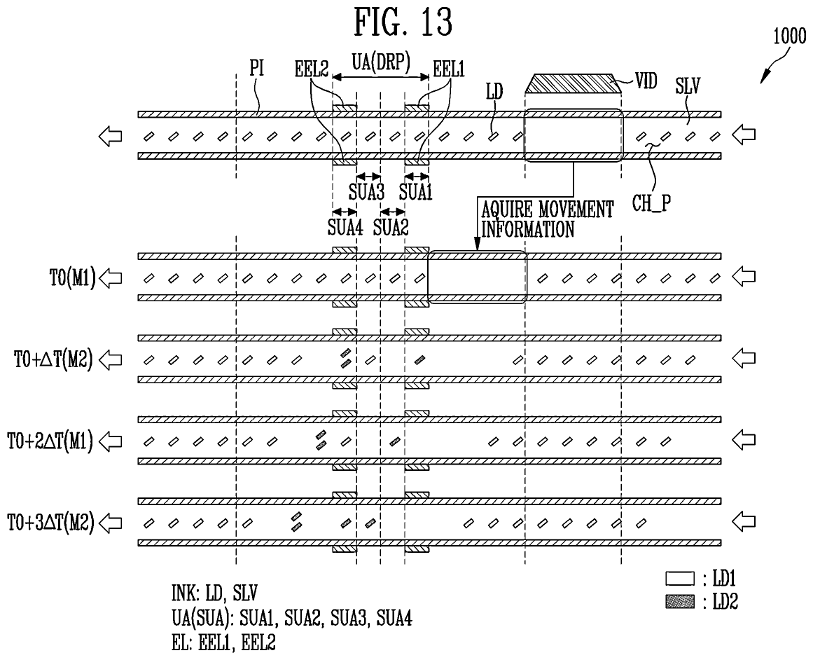

FIG. 7 is a schematic sectional view illustrating the print head unit 20 in accordance with an embodiment. FIG. 8 is a schematic sectional view illustrating the element-movement control module 1000 in accordance with an embodiment. FIGS. 9 and 10 are schematic sectional views illustrating the element-movement control module 1000 according to an embodiment for describing an arrangement structure of an electrode part EL in accordance with an embodiment. FIG. 11 is a schematic view illustrating an operation mode of the element-movement control module 1000 in accordance with an embodiment. FIG. 12 is a schematic sectional view for describing the operation mode of the element-movement control module 1000 in accordance with an embodiment. FIG. 13 is a schematic sectional view illustrating a structure in which the element-movement control module 1000 in accordance with an embodiment further may include an inspection part.

Referring to FIGS. 7 and 8, the print head unit 20 may include the element-movement control module 1000. In an embodiment, the print head unit 20 may include a body channel CH_B, an ink channel CH_P, a nozzle channel CH_N, and a recycle channel CH_R. In an embodiment, the print head unit 20 may include a body pipe PF and a nozzle plate NP.

The ink INK provided from the reservoir 40 may be provided to the body channel CH_B, the ink channel CH_P, the nozzle channel CH_N, and the recycle channel CH_R that are fluidly connected to each other. In an embodiment, the body pipe PF may include material having relatively high hardness, may define an area where the body channel CH_B and the recycle channel CH_R are formed, and may form an area where the element-movement control module 1000 is formed. The body pipe PF may be referred to as a body part or internal housing.

The ink INK may move through the body channel CH_B, and may move through the interior of a pipe part PI through the ink channel CH_P that is connected to at least a portion of the body channel CH_B. In an embodiment, the body channel CH_B may be connected, as a common channel, to two or more ink channels CH_P at different positions. For example, the ink channel CH_P may include two or more ink channels. A portion of the body channel CH_B may be fluidly connected to an ink channel CH_P at a first position, and another portion of the body channel CH_B may be fluidly connected to an ink channel CH_P at a second position different from the first position.

The ink channel CH_P may have a diameter less than that of the body channel CH_B. In an embodiment, the electrode part EL may be selectively disposed in the ink channel CH_P having a relatively small diameter to form an electric field for appropriately controlling movement of the light emitting elements LD. For example, the ink channel CH_P may have a micro-scale diameter. However, the disclosure is not limited to the aforementioned example.

At least some of the ink INK passing through the ink channel CH_P may be ejected to the outside through the nozzle channel CH_N. For example, the nozzle plate NP may form a nozzle hole NH along which the ink INK can move. The ink INK may be ejected to the outside through the nozzle hole NH. The nozzle plate NP and the nozzle hole NH may form a nozzle part.

At least another portion of the ink INK passing through the ink channel CH_P may be recycled through the recycle channel CH_R and moved back to the reservoir 40 by the pump 60.

The element-movement control module 1000 may include the pipe part PI and the electrode part EL. In an embodiment, the element-movement control module 1000 may be disposed in the area defined in the body pipe PF.

The pipe part PI may be disposed in the area defined in the body pipe PF. The pipe part PI may be coupled or connected and fastened to at least a portion of the body pipe PF. The position of the pipe part PI may be appropriately changed, and is not limited to a specific example.

In an embodiment, the pipe part PI may include a pipe.

The pipe part PI may include material having a relatively high hardness. In an embodiment, the pipe part PI may include non-conductive material (for example, substantially non-conductive material). For example, the pipe part PI may include one or more among the group consisting of glass, quartz material, and non-conductive polymers. However, the disclosure is not limited to the aforementioned example.

In an embodiment, as the pipe part PI may include non-conductive material, the electrode part EL may appropriately form an electric field in an internal area defined in the pipe part PI.

The pipe part PI may define the ink channel CH_P. The ink channel CH_P may be fluidly connected to the body channel CH_B, the nozzle channel CH_N, and the recycle channel CH_R. The ink channel CH_P may be formed to face the nozzle hole NH. In an embodiment, the ink channel CH_P may overlap the electrode part EL in a direction (for example, a diameter direction of the pipe part PI).

The electrode part EL may be disposed on a surface of the pipe part PI. The electrode part EL may be disposed on an outer surface of the pipe part PI.

The electrode part EL may include conductive material. For example, the electrode part EL may include an electrode to which a voltage can be applied. For example, the electrode part EL may include one or more among the group consisting of molybdenum (Mo), magnesium (Mg), silver (Ag), platinum (Pt), palladium (Pd), gold (Au), nickel (Ni), neodymium (Nd), iridium (Ir), chromium (Cr), titanium (Ti), copper (Cu), and aluminum (Al). However, the disclosure is not limited to the foregoing example.

In an embodiment, the electrode part EL may include a pair of electrodes that overlap each other in a cross-sectional direction of the pipe part PI at a given location. For example, the electrode part EL may include a first side electrode SEL1 and a second side electrode SEL2.

In an embodiment, the first side electrode SEL1 and the second side electrode SEL2 may be disposed on opposite sides and face each other. The first side electrode SEL1 may be disposed on a first side S1 of the pipe part PI. The second side electrode SEL2 may be disposed on a second side S2 of the pipe part PI. The first side S1 and the second side S2 may be opposite to each other, and may face each other with the ink channel CH_P interposed therebetween.

In an embodiment, the first side electrode SEL1 and the second side electrode SEL2 may form an electric field in the ink channel CH_P. For example, an AC voltage may be applied to the first side electrode SEL1, and a ground voltage may be applied to the second side electrode SEL2. By way of example, in an embodiment, a DC voltage may be applied to the first side electrode SEL1, and a relatively low DC voltage may be applied to the second side electrode SEL2. However, the disclosure is not limited to the aforementioned example.

Referring to FIGS. 9 and 10, the electrode part EL may be disposed in a given unit area UA among areas of the pipe part PI that are sectioned from each other according to a selectable criteria. For example, in case that ejecting the ink INK at a time, the print head unit 20 (for example, the nozzle part) may discharge a drop volume DRP (for example, a 1-drop volume) of ink INK. In an embodiment, an area capable of receiving the volume of ink INK corresponding to the drop volume DRP may be determined as a unit area UA. The pipe part PI may be divided into a plurality of unit areas UA. For example, the volume of the ink channel CH_P in the unit area UA may correspond to (for example, be substantially a same as) the drop volume DRP.

The electrode part EL may be disposed in the unit area UA. Since a range in which the electrode part EL is disposed may be determined based on the unit area UA, the content of light emitting elements LD in the ink INK may be suitably controlled based on the drop volume DRP. In an embodiment, the length of unit area UA may be determined depending on the drop volume DRP to be ejected and a bottom surface area of the pipe part PI.

The electrode part EL may include a plurality of electrode parts spaced apart from each other in a longitudinal direction of the pipe part PI (for example, a direction in which the ink channel CH_P extends). For example, the electrode part EL may include n or more electrode parts (where n is an even number of 2 or more) spaced apart from each other in the longitudinal direction of the pipe part PI. For example, the electrode part EL may include n or more electrode parts (where n is an even number of 4 or more) spaced apart from each other in the longitudinal direction of the pipe part PI.

In an embodiment, the number of electrode parts EL may be defined based on the number of pairs, each including the first side electrode SEL1 and the second side electrode SEL2.

For example (refer to FIG. 9), the electrode part EL may include two electrode parts. The electrode part EL may include a first edge electrode part EEL1 and a second edge electrode part EEL2. The first edge electrode part EEL1 may be adjacent to a first end of the unit area UA. The second edge electrode part EEL2 may be adjacent to a second end of the unit area UA. Each of the first edge electrode part EEL1 and the second edge electrode part EEL2 may include side electrodes SEL1 and SEL2 that overlap each other in a cross-sectional direction of the pipe part PI.

By way of example, for example (refer to FIG. 10), the electrode part EL may include four electrode parts. The electrode part EL may include a first edge electrode part EEL1 and a second edge electrode part EEL2, and may include a first inner electrode part IEL1 and a second inner electrode part IEL2. Each of the first edge electrode part EEL1 the second edge electrode part EEL2, the first inner electrode part IEL1, and the second inner electrode part IEL2 may include side electrodes SEL1 and SEL2 that overlap each other in a cross-sectional direction of the pipe part PI.

In an embodiment, the electrode parts EL that are arranged or disposed in the longitudinal direction of the pipe part PI may be spaced apart from each other with a sub-unit area SUA interposed therebetween. For example, the adjacent electrode parts EL may be disposed adjacent to each other with a sub-unit area SUA interposed therebetween. By way of example, in an embodiment, the adjacent electrode parts EL may be disposed adjacent to each other with two sub-unit areas SUA interposed therebetween. Accordingly, in the unit area SUA, the electrode parts EL with the sub-unit areas SUA as partitioning units may be alternately arranged or disposed. The sub-unit area SUA may be a basic unit area of an area where the electrode part EL is disposed or not disposed. For example, the range of the sub-unit area SUA may correspond to (for example, be substantially a same as) the range of an area covered by an electrode part EL (for example, an area where an electric field is formed).

For example (refer to FIG. 9), the sub-unit areas SUA included in the unit area UA may include a first sub-unit area SUA1, a second sub-unit area SUA2, a third sub-unit area SUA3, and a fourth sub-unit area SUA4. The first edge electrode part EEL1 may be disposed in the first sub-unit area SUA1. The second edge electrode part EEL2 may be disposed in the second sub-unit area SUA2.

For example (refer to FIG. 10), the sub-unit areas SUA included in the unit area UA may include a first sub-unit area SUA1, a second sub-unit area SUA2, a third sub-unit area SUA3, a fourth sub-unit area SUA4, a fifth sub-unit area SUA5, a sixth sub-unit area SUA6, a seventh sub-unit area SUA7, and an eighth sub-unit area SUA8. The first edge electrode part EEL1 may be disposed in the first sub-unit area SUA1. The first inner electrode part IEL1 may be disposed in the third sub-unit area SUA3. The second inner electrode part IEL2 may be disposed in the sixth sub-unit area SUA6. The second edge electrode part EEL2 may be disposed in the eighth sub-unit area SUA8.

In an embodiment, the number of sub-unit areas SUA may be an even number. For example, the unit area UA may be divided based on an even number, distinguishing areas where the electrode part EL is disposed or not disposed. The unit area UA may be relatively finely divided, such as into eight sub-unit areas SUA, thus defining areas where the electrode part EL can be disposed.

The element-movement control module 1000 including the electrode part EL may limit movement of the light emitting element LD. According to the element-movement control module 1000 including the above-mentioned structural characteristics, the risk of including no light emitting element LD in a drop unit in which the ink INK is ejected may be prevented. Moreover, the risk of including an amount of light emitting elements LD, exceeding an intended quantity, in a drop unit by which the ink INK is ejected may also be prevented.

In this regard, the operation mode of the element-movement control module 1000 (or the print head unit 20) in accordance with an embodiment will be described with reference to FIGS. 11 and 12. Subsequently, detailed structure implementation will be described in connection with the manufacturing method.

Referring to FIGS. 11 and 12, the element-movement control module 1000 (or the print head unit 20) may operate in a first mode M1 or a second mode M2.

For the sake of convenience in the explanation, the element-movement control module 1000 (or the print head unit 20) will be described based on an operation pattern, which can operate in the first mode M1 from a reference time point TO and operate in the second mode M2 from a first elapsed time point T0+ΔT after a unit time ΔT from the reference time point TO. For example, the element-movement control module 1000 (or the print head unit 20) may operate in the first mode M1 for the unit time ΔT based on the reference time point TO. The element-movement control module 1000 (or the print head unit 20) may operate in the second mode M2 for the unit time ΔT based on the first elapsed time point T0+ΔT. For example, the element-movement control module 1000 may operate for a same time in each of the first mode M1 and the second mode M2.

In an embodiment, the element-movement control module 1000 may enter the first mode M1. In case that operating in the first mode M1, the element-movement control module 1000 may not restrict the movement of the light emitting element LD, so that the light emitting element LD may pass through the ink channel CH_P. In an embodiment, in the case where the element-movement control module 1000 operates in the first mode M1, an electrical signal (for example, a movement control signal or voltage) may not be applied to the first side electrode SEL1 and the second side electrode SEL2, and an electric field may not be substantially formed between the first side electrode SEL1 and the second side electrode SEL2.

In an embodiment, the element-movement control module 1000 may enter the second mode M2. In case that operating in the second mode M2, the element-movement control module 1000 may restrict the movement of the light emitting element LD, whereby it may be difficult for the light emitting element LD to pass through the sub-unit area SUA in which the electrode part EL is disposed. In an embodiment, in the case where the element-movement control module 1000 operates in the second mode M2, an electrical signal (for example, a movement control signal or voltage) may be applied to the first side electrode SEL1 and the second side electrode SEL2, and an electric field may be formed between the first side electrode SEL1 and the second side electrode SEL2.

Hereinafter, for the sake of convenience in the explanation, a light emitting element LD of which movement is restricted by the electric field formed by the electrode part EL is referred to as a first light emitting element LD1, and is represented in the drawings by a solid line box without patterning. A light emitting element LD of which movement has been restricted by the electric field formed by the electrode part EL is referred to as a second light emitting element LD2, and is represented in the drawings by a box with patterning.

In an embodiment, as the movement of the light emitting elements LD is not restricted at a reference time point TO, the ink INK may flow in a flow direction (for example, successively flow).

In an embodiment, the movement of the light emitting elements LD may be restricted at the first elapsed time point T0+ΔT. The second light emitting elements LD2 may not pass through an area in which the electrode parts EL are disposed (for example, the first sub-unit area SUA1 and the fourth sub-unit area SUA4). The first light emitting elements LD1 corresponding to an area where the electrodes EL are not disposed may move in a direction along the flow of the ink INK.

Experimentally, the light emitting elements LD in the ink INK may be provided in a dispersed state in the solvent SLV, and it may be difficult to completely uniformly distribute the light emitting elements LD in the ink INK. In this case, in case that the print head unit 20 ejects the ink INK in drop volumes DRP, there may be a risk that the number of light emitting elements LD included in each drop volume DRP may vary. In the case where the number of light emitting elements LD in each drop volume DRP varies, there may be a deviation in the number of light emitting elements LD disposed for each of the sub-pixels SPX in the display area DA of the display device DD. In this case, there is a concern that dark spots may be observed in some areas, or differences in emission efficiency may occur, thus leading to a degradation in visibility. Furthermore, there is a risk of an excessive application of light emitting elements LD in some areas, thus leading to an unnecessary increase in production cost.

However, in accordance with an embodiment, the element-movement control module 1000 may operate alternately in the first mode M1 and the second mode M2. Therefore, movement of the light emitting elements LD in some channels (for example, the ink channel CH_P) to which the ink INK is provided may be restricted by the element-movement control module 1000. The risk of excessive reduction or increase in the number of light emitting elements LD in some ink INK in drop volume DRP may be prevented.

The unit time ΔT during which the element-movement control module 1000 operates in each of the first mode M1 and the second mode M2 may be determined based on the flow rate of the ink INK and the length of the sub-unit area SUA. For example, the unit time ΔT may be defined, based on the flow rate of the ink INK, as the time it takes for the ink INK to move the length of the sub-unit area SUA. In other words, a time section during which the movement of light emitting elements LD is restricted or not restricted may correspond to distinction between areas where the electrode parts EL are disposed or not disposed. Thus, the flow of the light emitting elements LD may be more precisely controlled.

A structure in which the element-movement control module 1000 in accordance with an embodiment further may include an inspection part VID will be described with reference to FIG. 13. In FIG. 13, for the sake of convenience in the explanation, there is illustrated the operation of the element-movement control module 1000 at the reference time point TO and subsequent time points, for example, first to fifth elapsed time points T0+ΔT to T0+3ΔT.

In an embodiment, the element-movement control module 1000 may further include the inspection part VID. The inspection part VID may be spaced apart from the electrode parts EL in the longitudinal direction of the pipe part PI. The inspection part VID may be disposed adjacent to the outer surface of the pipe part PI.

The inspection part VID may be disposed in an area spaced, by one or more unit areas UA, apart from the unit area UA where the electrode part EL is positioned. For example, n unit areas UA (where n is a natural number of 1 or more) may be formed between the inspection part VID and the electrode parts EL.

The inspection part VID may observe the flow of light emitting elements LD in the ink channel CH_P, and acquire visual information about the flow of the light emitting elements LD. For example, the inspection part VID may include a camera. The inspection part VID may acquire information about the movement of the light emitting elements LD in the ink channel CH_P.

The inspection part VID may be positioned ahead of the electrode part EL, based on the flow direction of the ink INK. Hence, the inspection part VID may verify that the amount of light emitting elements LD included in some areas of the ink INK is not abnormal (for example, not excessively small or not present). The electrode part EL may operate in the first mode M1 or the second mode M2 based on the verified information.

For example, the inspection part VID may verify that no light emitting element LD is included in some areas of the ink INK corresponding to the drop volume DRP at the reference time point TO. Based on the information provided from the inspection part VID, information about movement of some portions of the ink INK in which the light emitting elements LD are not normally included. For example, based on the number of unit areas UA between the inspection part VID and the electrode parts EL, acquired can be information about the time it takes for the some portions of the ink INK in which the light emitting elements LD are not normally included to reach the unit area UA in which the electrode parts EL are positioned. For example, in FIG. 13, there is illustrated an embodiment where an abnormal area reaches the electrode parts EL after the unit time ΔT from the reference time point TO.

For example, the element-movement control module 1000 may continue to operate in the first mode M1 for the unit time ΔT from the first elapsed time point T0+ΔT. Subsequently, the element-movement control module 1000 may operate in the second mode M2 for the unit time ΔT from the second elapsed time point T0+2ΔT. Thereafter, the element-movement control module 1000 may operate in the first mode M1 for the unit time ΔT from the third elapsed time point T0+3ΔT. Subsequently, the element-movement control module 1000 may operate in the second mode M2 for the unit time ΔT from the fourth elapsed time point T0+4ΔT. Here, movement of some light emitting elements LD is restricted, so that location distribution of the second light emitting elements LD2 may be changed. Referring to the distribution of the light emitting elements LD of FIG. 13, it can be understood that at least a light emitting element LD is included in ink INK in a volume corresponding to the drop volume DRP, compared to a time point of initial entry of ink INK. In other, the risk of exclusion of light emitting element LD in the drop volume of some ink INK may be reduced. The above-mentioned technical effect may be provided in a same manner even in an implementation structure where the inspection part VID is not included. In the case where an additional inspection part VID is included, the operational reliability of the element-movement control module 1000 can be enhanced.

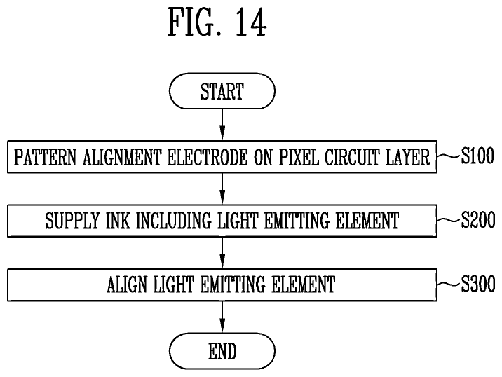

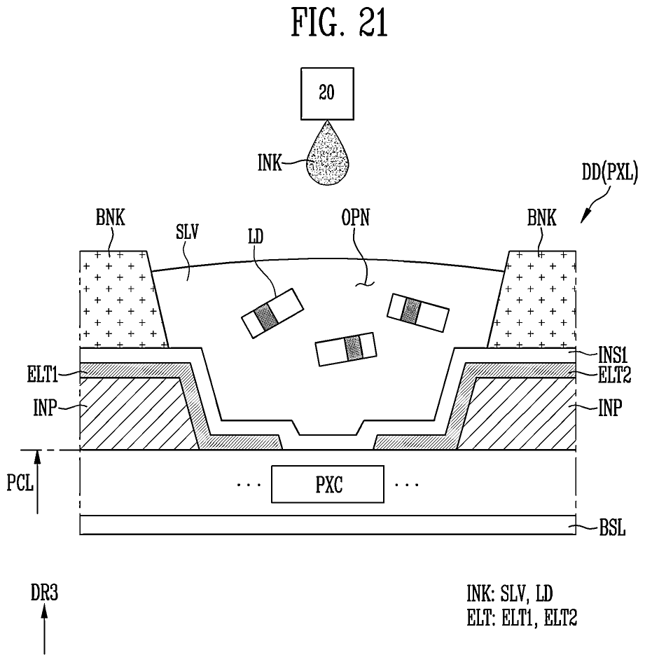

A method of manufacturing a display device using the manufacturing apparatus 1 in accordance with an embodiment will be described with reference to FIGS. 14 to 22.

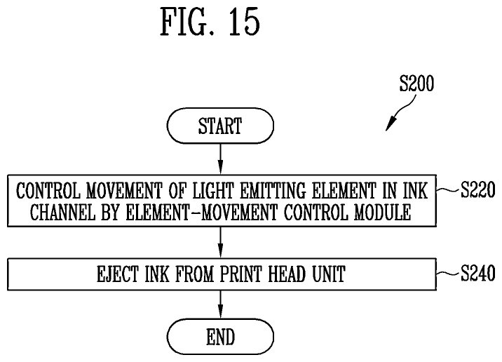

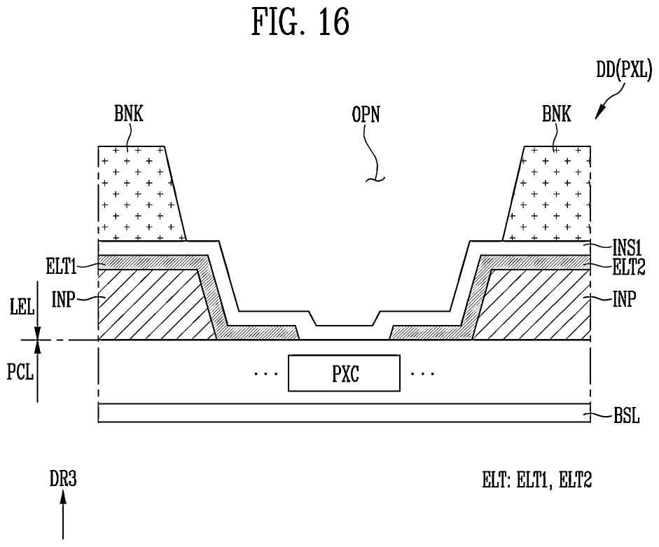

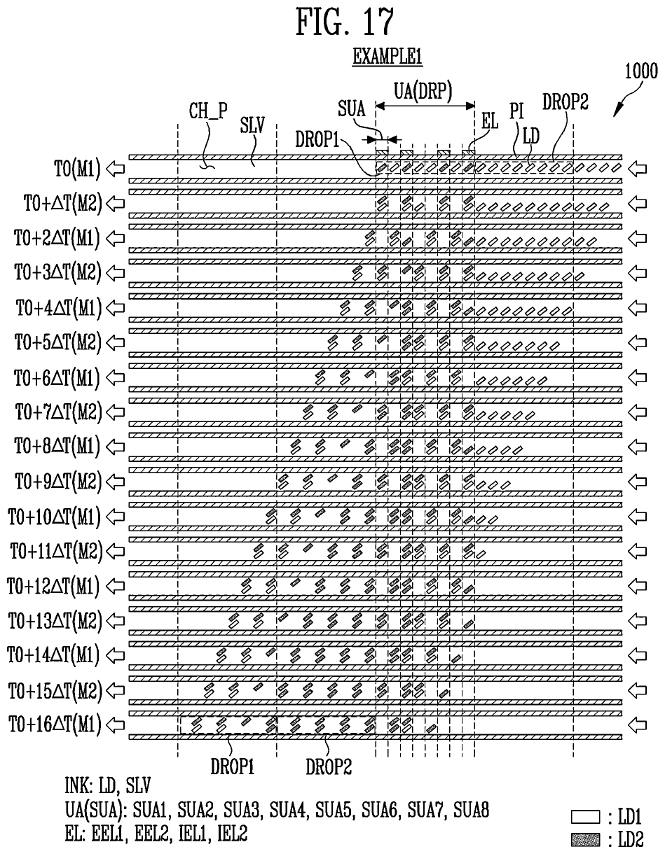

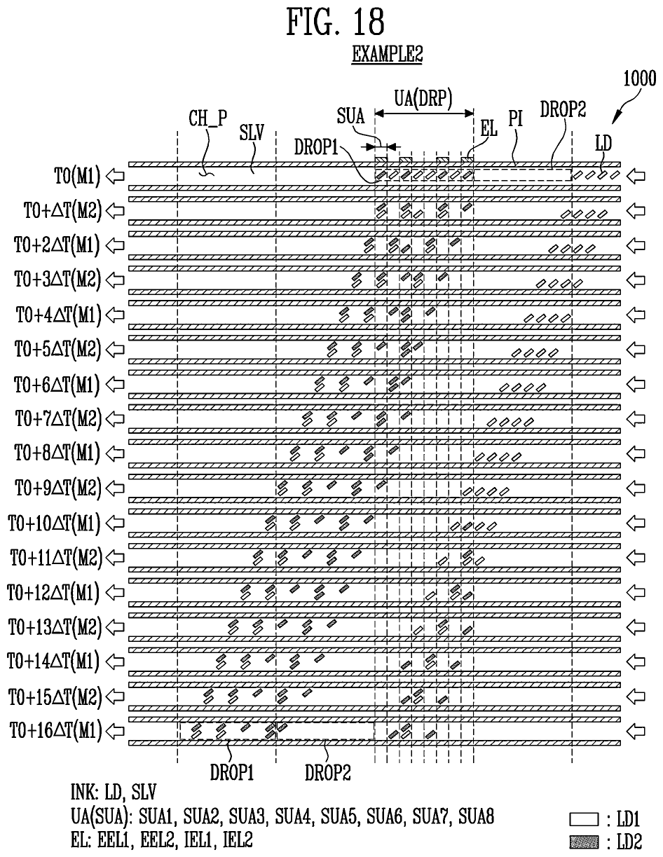

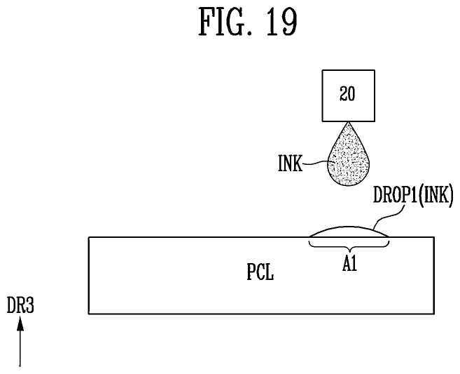

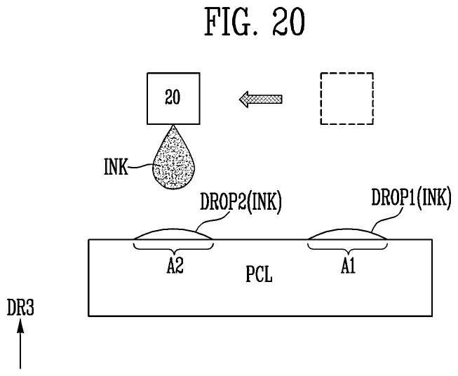

FIG. 14 is a flowchart illustrating a method of manufacturing the display device using the manufacturing apparatus 1 in accordance with an embodiment. FIG. 15 is a flowchart illustrating in detail steps in the method of manufacturing the display device using the manufacturing apparatus in accordance with an embodiment. FIGS. 16, 21, and 22 are schematic sectional views illustrating, by process steps, the method of manufacturing the display device in accordance with an embodiment. For the sake of convenience in the explanation, FIGS. 16, 21, and 22 are diagrams corresponding to the cross-sectional structure depicted in FIG. 4. FIGS. 17 and 18 are schematic views illustrating operation aspects of the element-movement control module 1000 in accordance with an embodiment. For the sake of convenience in the explanation, FIGS. 17 and 18 illustrate the above-stated structure depicted in FIG. 10. FIGS. 19 and 20 are schematic views illustrating ejection of ink INK in accordance with an embodiment. FIGS. 19 and 20 schematically illustrate a process in which the print head unit 20 successively ejects the ink INK.

Referring to FIG. 14, the method of manufacturing the display device in accordance with embodiment may include step S100 of patterning the alignment electrode on the pixel circuit layer, step S200 of supply ink including light emitting elements, and step S300 of aligning the light emitting elements.

Referring to FIGS. 14 and 16, at step S100 of patterning the alignment electrode on the pixel circuit layer, the base layer BSL may be prepared. The conductive layers and the insulating layers may be disposed on the base layer BSL to form the pixel circuit PXC, thus providing the pixel circuit layer PCL. The alignment electrodes ELT may be patterned on the pixel circuit layer PCL (for example, the base layer BSL).

The conductive layers or the insulating layer on the base layer BSL may be formed based on a selectable process for manufacturing a semiconductor device. For example, the conductive layers or the insulating layers on the base layer BSL may be formed through a photolithography process, and may be deposited by various methods (for example, sputtering, chemical vapor deposition, and the like within the spirit and the scope of the disclosure). However, the disclosure is not limited to a specific example.

At the present step, before the alignment electrode ELT is deposited, the insulating pattern INP may be patterned on the pixel circuit layer PCL. After the alignment electrode ELT is patterned, the first insulating layer INS1 may be formed on the first electrode ELT1 and the second electrode ELT2. After the first insulating layer INS1 is formed, the bank BNK may be patterned (for example, formed) to form the opening OPN.

Referring to FIGS. 14, 15, and 17 to 21, step S200 of supplying the ink including the light emitting elements may be performed. Step S200 of supplying the ink may include step S220 at which the element-movement control module controls movement of the light emitting elements in the ink channel, and step S240 of ejecting ink from the print head unit.

With reference to two examples illustrated in FIGS. 17 and 18, step S220 at which the element-movement control module controls the movement of the light emitting elements in the ink channel will be described.

As described above, the light emitting elements LD may be dispersed and disposed in the ink INK. In the area where the electrode parts EL are disposed, portion of the ink INK with the light emitting elements LD substantially uniformly distributed may move, and portion of the ink INK without the light emitting elements LD may move.

In FIGS. 17 and 18, there are embodiments where a first drop volume DROP1 of ink and a second drop volume DROP2 of ink defined based on the drop volume DRP are successively moved in the ink channel CH_P. For the sake of convenience in the explanation, descriptions will be based on the case where eight light emitting elements LD are included in the drop volume DRP of ink as a target quantity (for example, an intended quantity). Accordingly, it may be an example for the drop volume DRP of the ejected ink INK to include eight light emitting elements LD, and at least one light emitting element LD may be required to be included therein.

FIG. 17 illustrates, a first example, an implementation aspect in which eight light emitting elements LD are included in each of the first drop volume DROP1 and the second drop volume DROP2. FIG. 18 illustrates, a second example, an implementation aspect in which eight light emitting elements LD are included in the first drop volume DROP1 while no light emitting element LD is included in the second drop volume DROP2.

In an embodiment, in the first example and the second example, to control the movement of the light emitting elements LD for each of the first drop volume DROP1 and the second drop volume DROP2, the element-movement control module 1000 may operate alternately in the first mode M1 and the second mode M2. In an embodiment, the first drop volume DROP1 and the second drop volume DROP2 may correspond to each other. For example, the first drop volume DROP1 and the second drop volume DROP2 may be substantially a same as each other.

For example, in each of the first example and the second example, the element-movement control module 1000 may operate in the first mode M1 for the unit time ΔT from a reference time point TO. In each of the first example and the second example, the element-movement control module 1000 may operate in the second mode M2 for the unit time ΔT from a first elapsed time point T0+ΔT. In each of the first example and the second example, the element-movement control module 1000 may operate in the first mode M1 for the unit time ΔT from a second elapsed time point T0+2ΔT. In each of the first example and the second example, the element-movement control module 1000 may operate in the second mode M2 for the unit time ΔT from a third elapsed time point T0+3ΔT. In each of the first example and the second example, the element-movement control module 1000 may operate in the first mode M1 for the unit time ΔT from a fourth elapsed time point T0+4ΔT. In each of the first example and the second example, the element-movement control module 1000 may operate in the second mode M2 for the unit time ΔT from a fifth elapsed time point T0+5ΔT. In each of the first example and the second example, the element-movement control module 1000 may operate in the first mode M1 for the unit time ΔT from a sixth elapsed time point T0+6ΔT. In each of the first example and the second example, the element-movement control module 1000 may operate in the second mode M2 for the unit time ΔT from a seventh elapsed time point T0+7ΔT. In each of the first example and the second example, the element-movement control module 1000 may operate in the first mode M1 for the unit time ΔT from an eighth elapsed time point T0+8ΔT. In each of the first example and the second example, the element-movement control module 1000 may operate in the second mode M2 for the unit time ΔT from a ninth elapsed time point T0+9ΔT. In each of the first example and the second example, the element-movement control module 1000 may operate in the first mode M1 for the unit time ΔT from a tenth elapsed time point T0+10ΔT. In each of the first example and the second example, the element-movement control module 1000 may operate in the second mode M2 for the unit time ΔT from an eleventh elapsed time point T0+11ΔT. In each of the first example and the second example, the element-movement control module 1000 may operate in the first mode M1 for the unit time ΔT from a twelfth elapsed time point T0+12ΔT. In each of the first example and the second example, the element-movement control module 1000 may operate in the second mode M2 for the unit time ΔT from a thirteenth elapsed time point T0+13ΔT. In each of the first example and the second example, the element-movement control module 1000 may operate in the first mode M1 for the unit time ΔT from a fourteenth elapsed time point T0+14ΔT. In each of the first example and the second example, the element-movement control module 1000 may operate in the second mode M2 for the unit time ΔT from a fifteenth elapsed time point T0+15ΔT. In each of the first example and the second example, the element-movement control module 1000 may operate in the first mode M1 for the unit time ΔT from a sixteenth elapsed time point T0+16ΔT.

With reference to FIG. 17, as the described operations are performed, the locations of some second light emitting elements LD2 may be changed. For example, some of the light emitting elements LD included in the first drop volume DROP1 may be changed to be included in the second drop volume DROP2. Some of the light emitting elements LD included in the second drop volume DROP2 may be changed to be included in the first drop volume DROP1. In other words, in the case where there is a sufficient number of light emitting elements LD included in the areas of the ink INK, it can be verified that there may be no risk of an excessive increase in the number of light emitting elements LD included in some drop volumes DRP.

With reference to FIG. 18, as the described operations are performed, the locations of some second light emitting elements LD2 may be changed. For example, some of the light emitting elements LD included in the first drop volume DROP1 may be changed to be included in the second drop volume DROP2. In other words, even if some areas of the ink INK do not include light emitting elements LD, it can be verified that at least one light emitting element LD is included in each ejected drop volume DRP.

The described technical effects may be provided by the structure in which an even number of sub-unit areas SUA is included in the unit area UA for relatively fine differentiation and distinction, and the electrode parts EL are disposed in the respective sub-unit areas SUA provided in first and second ends of at least the unit area UA. For example, in the case where the unit area UA is divided into two sub-unit areas SUA, the ink INK of some drop volumes DRP may include no light emitting element LD, as the movement of the light emitting elements LD is restricted or not restricted based on a half area of the drop volume DRP. Furthermore, in the case where an odd number of sub-unit areas SUA is included in the unit area UA, the area where the electrode parts EL restrict the movement of the light emitting elements LD may expand. Therefore, in some examples (for example, FIG. 17), there may be a risk of including a larger number of light emitting elements LD than intended in the ink INK of the drop volume DRP. In conclusion, in the disclosure, at least a light emitting element LD is included in the drop volume DRP without incurring the above-stated risks, and a relatively uniform number of light emitting elements LD may be included in the drop volume DRP. Consequently, the risk of an unnecessary increase in production cost can be prevented.

Referring to FIGS. 19 to 21, at step S240 of ejecting ink from the print head unit, the ink INK may be provided (for example, ejected) onto the base layer BSL.

At the present step, the ink INK ejected from the printed head unit 20 may be supplied into the opening OPN defined in the bank BNK. The light emitting elements LD may be dispersed and disposed in the solvent SLV before being aligned.

In an embodiment, the print head unit 20 may supply the first drop volume DROP1 of ink INK to a first area A1. The print head unit 20 may supply the second drop volume DROP2 of ink INK to a second area A2 formed at a position different from the first area A1.

As described above, at least a light emitting element LD may be included in each of the inks INK of the drop volume DRP ejected at different time points, so that at least a light emitting element LD may be disposed in each of the first area A1 and the second area A2.

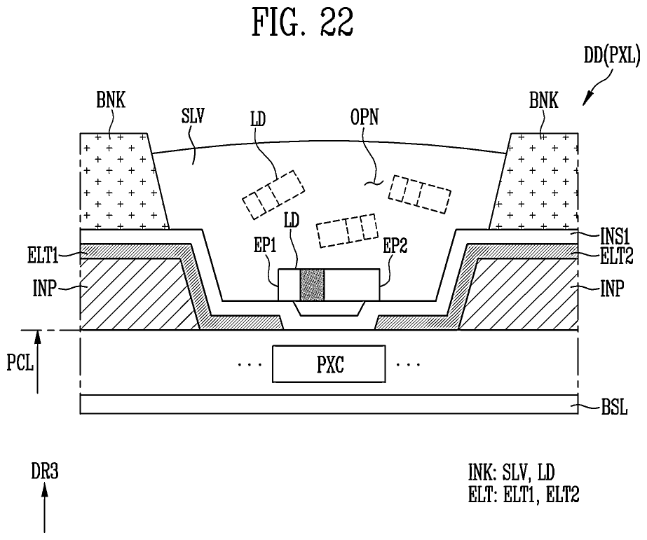

Referring to FIGS. 14 and 22, at step S300 of aligning the light emitting elements, the light emitting elements may be aligned (for example, disposed) based on an electric field formed by the alignment electrode ELT.

At the present step, a first alignment signal may be supplied to the first electrode ELT1, and a second alignment signal may be supplied to the second electrode ELT2, so that an electric field may be formed between the first electrode ELT1 and the second electrode ELT2. The light emitting elements LD may be aligned between the first electrode ELT1 and the second electrode ELT2, based on the formed electric field. For example, each of the light emitting elements LD may be aligned such that the first end EP1 thereof faces the first electrode ELT1 and the second end EP2 thereof faces the second electrode ELT2.

Thereafter, although not illustrated, the solvent SLV may be removed (for example, through a dry process or the like within the spirit and the scope of the disclosure), and the second insulating layer INS2 may be patterned on the light emitting elements LD. The connection electrode CNE may be patterned to be electrically connected to the light emitting elements LD.

Various embodiments may provide an apparatus for manufacturing a display device, a method of manufacturing the display device using the manufacturing apparatus, and a display device manufactured by the method, which may adjust the amount of light emitting elements, thus reducing the production cost, and making the amount of light emitting elements provided to a pixel uniform.

While various embodiments have been described above, those skilled in the art will appreciate that various modifications, additions and substitutions are possible, without departing from the scope and spirit of the disclosure.

Therefore, the embodiments disclosed in this specification are only for illustrative purposes rather than limiting the technical spirit of the disclosure. The scope of the disclosure may also be defined by the accompanying claims.

What is claimed is:

1. An apparatus of manufacturing a display device, comprising:
a reservoir that receives ink including a light emitting element and a solvent;
an element-movement control module, the element-movement control module including a pipe part defining an ink channel fluidly connected to the reservoir, and an electrode part disposed on a surface of the pipe part; and
a nozzle part that ejects the ink outward, wherein
the element-movement control module operates in a first mode or a second mode,
in case that the element-movement control module operates in the first mode, movement of the light emitting element is unrestricted, and
in case that the element-movement control module operates in the second mode, the electrode part forms an electric field, and the movement of the light emitting element in the ink channel is restricted at least in an area corresponding to a position at which the electrode part is disposed.

2. The apparatus according to claim 1, wherein the pipe part includes a material that substantially has non-conductivity that allows the electric field formed by the electrode part to be formed in the ink channel.

3. The apparatus according to claim 1, wherein the electrode part includes a first side electrode and a second side electrode that form a pair and are spaced apart from each other with the ink channel disposed between the first side electrode and the second side electrode.

4. The apparatus according to claim 1, wherein
the pipe part is divided into a plurality of unit areas,
the electrode part is disposed in a unit area among the plurality of unit areas, and
a volume of the ink channel in the unit area among the plurality of unit areas corresponds to a drop volume of the ink in case that the ink is ejected once from the nozzle part.

5. The apparatus according to claim 4, wherein
the electrode part includes a plurality of electrode parts spaced apart from each other in a longitudinal direction of the pipe part, and
the plurality of electrode parts comprises a first edge electrode part adjacent to a first end of the unit area among the plurality of unit areas, a second edge electrode part adjacent to a second end of the unit area among the plurality of unit areas, and an inner electrode part disposed between the first edge electrode part and the second edge electrode part.

6. The apparatus according to claim 5, wherein
the unit area among the plurality of unit areas comprises a plurality of sub-unit areas, and
the plurality of electrode parts are adjacent to each other with the plurality of sub-unit areas disposed between the plurality of electrode parts.

7. The apparatus according to claim 6, wherein a number of the plurality of sub-unit areas is an even number of 4 or more.

8. The apparatus according to claim 6, wherein
the element-movement control module operates for an identical unit time in each of the first mode and the second mode, and
the unit time is a time taken for the ink to move through the plurality of sub-unit areas while moving in the ink channel.

9. The apparatus according to claim 8, wherein the element-movement control module operates alternately in the first mode and the second mode.

10. The apparatus according to claim 8, further comprising:
an inspection part that is spaced apart from the electrode part in the longitudinal direction of the pipe part and that acquires information about the movement of the light emitting element in the ink channel.

11. The apparatus according to claim 10, wherein, in case that the inspection part acquires movement information that the light emitting element is not normally included in some areas of the ink in the ink channel, after a time based on a distance between the inspection part and the electrode part has elapsed, the element-movement control module continues to operate in the first mode, and after the unit time has further elapsed, the element-movement control module enters the second mode.

12. The apparatus according to claim 1, wherein
the nozzle part and the element-movement control module are disposed in a print head part,
the apparatus further comprises:
a main channel fluidly connecting the print head part with the reservoir; and
a body channel formed in the print head part and fluidly connecting the main channel with the ink channel,
the body channel has a diameter greater than a diameter of the ink channel, and
the element-movement control module is not disposed in the body channel.

13. The apparatus according to claim 12, wherein
the print head part further comprises a body pipe forming a recycle channel fluidly connected to the ink channel,
the recycle channel is fluidly connected to the reservoir, and
the body pipe forms space in which the element-movement control module is disposed.

14. A method of manufacturing a display device using an apparatus for manufacturing the display device,
the apparatus comprising:
a reservoir that receives ink including a light emitting element and a solvent;
an element-movement control module comprising a pipe part defining an ink channel fluidly connected to the reservoir, and an electrode part disposed on a surface of the pipe part, the element-movement control module operating in a first mode or a second mode; and
a nozzle part that ejects the ink outward,
the method comprising:
patterning a first electrode and a second electrode on a base layer;
supplying the ink provided from the nozzle part onto the base layer; and
aligning the light emitting element, based on an electric field formed between the first electrode and the second electrode,
the supplying of the ink comprises:
operating the element-movement control module in the first mode; and
operating the element-movement control module in the second mode,
the operating of the element-movement control module in the first mode comprises passing the light emitting element through an area corresponding to a position, at which the electrode part is disposed, in the ink channel, and
the operating of the element-movement control module in the second mode comprises restricting movement of the light emitting element in the area in the ink channel.

15. The method according to claim 14, further comprising:
patterning a bank defining an opening on the base layer, wherein
supplying the ink comprises providing the ink into the opening of the bank, and
the aligning of the light emitting element comprises supplying a first alignment signal to the first electrode; and supplying a second alignment signal different from the first alignment signal to the second electrode.

16. The method according to claim 14, wherein
the pipe part is divided into a plurality of unit areas,
the electrode part is disposed in a unit area among the plurality of unit areas,
a volume of the ink channel in the unit area among the plurality of unit areas corresponds to a drop volume of the ink in case that the ink is ejected once from the nozzle part, and
the electrode part includes a plurality of electrode parts spaced apart from each other in a longitudinal direction of the pipe part.

17. The method according to claim 16, wherein
the unit area among the plurality of unit areas comprises a plurality of sub-unit areas, and
the plurality of electrode parts are adjacent to each other with the sub-unit area among the plurality of unit areas disposed between the plurality of electrode parts, and
a number of the plurality of sub-unit areas is an even number of 4 or more.

18. The method according to claim 14, wherein the operating of the element-movement control module in the first mode and the operating of the element-movement control module in the second mode alternate.

19. The method according to claim 14, wherein
the supplying of the ink comprises:
supplying the ink of a first drop volume to a first area on the base layer; and
supplying the ink of a second drop volume to a second area on the base layer, and
at least the light emitting element is included in the ink of each of the first drop volume and the second drop volume.

20. A display device manufactured by the method according to claim 14, comprising:
the light emitting element aligned between the first electrode and the second electrode;
a first connection electrode electrically connected to a first end of the light emitting element; and
a second connection electrode electrically connected to a second end of the light emitting element.
